(19) United States
(12) Patent Application Publication
(10) Pub. No.: US 2009/0072225 A1
(43) Pub. Date: Mar. 19, 2009

(54) FLAT PANEL DISPLAY DEVICE HAVING ORGANIC THIN FILM TRANSISTOR AND MANUFACTURING METHOD THEREOF

(75) Inventors: Jae-Bon KOO, Daejeon (KR); Seung-Youl Kang, Daejeon (KR); Kyung-Soo Suh, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/112,593

(22) Filed: Apr. 30, 2008

(30) Foreign Application Priority Data
Sep. 18, 2007 (KR) 10-2007-0094559

(51) Int. Cl. H01L 51/30; H01L 51/00

(52) U.S. Cl. 257/40; 438/99; 257/E51.001; 257/E51.024

(57) ABSTRACT

Provided is a flat panel display device having an organic TFT and a manufacturing method thereof. The flat panel display device includes a first organic TFT having a first organic semiconductor active layer, and a second organic TFT having a second organic semiconductor active layer. At this point, the particle size of the organic semiconductor crystal of the first organic semiconductor active layer is greater than that of the organic semiconductor crystal of the second organic semiconductor active layer.

### CROSS-REFERENCE TO RELATED APPLICATIONS

This U.S. non-provisional patent application claims priority under 35 U.S.C. §119 of Korean Patent Application No. 10-2007-94559, filed on Sep. 18, 2007, the entire contents of which are hereby incorporated by reference.

### BACKGROUND OF THE INVENTION

The present invention disclosed herein relates to a flat panel display device, and more particularly, to a flat panel display device having an organic thin film transistor (TFT) and a manufacturing method thereof.

The present invention has been derived from a research conducted as a part of the information technology (IT) new growth power core technology development business by Ministry of Information and Communication, and Institute for Information Technology Advancement, Republic of Korea (Project management No. 2005-S-070-03, Project title: flexible display).

A TFT is used as a switching device or a driving device in a flat panel display device such as a liquid crystal display (LCD), an organic light emitting diodes (OLED) display, and an inorganic LED display. Since the switching device is used to control the operation of each pixel of the flat panel display device, it needs to have a reduced leakage current characteristic. Since the driving device is used to drive each pixel, it needs to have an increased turn-on current characteristic.

In case of a flat panel display device (e.g., OLED display or LCD) based on low-temperature polysilicon thin film transistor (LTPS TFT), the driving transistor and the switching transistor are manufactured in different channel lengths and different channel widths, respectively, to meet such technical requirements.

Meanwhile, unlike the polysilicon TFT, a recently proposed organic TFT can be manufactured using a very cheap process technology such as a printing technique. Also, the organic TFT can be manufactured on a flexible substrate such as a plastic substrate, because it can be formed by using low temperature process technology. Accordingly, it is expected that the organic TFT can be used as an active device for a large-sized flat panel display device or recently spotlighted flexible electronic products in substitution for an inorganic TFT such as a polysilicon TFT. For example, an OLED display using the organic TFT as an active device has a fast response time of I ms or less, and moreover, it has excellent technical characteristics related to visibility and a viewing angle. Also, since the OLED display does not require a backlight, it has a lower power consumption characteristic and a thinner thickness than those of an LCD. Accordingly, the OLED display is in the limelight as a next generation flat panel display device that will replace an LCD widely used recently.

However, a typical organic TFT is known to have relative low electron mobility and a relatively large leakage current compared to an inorganic TFT, and thus it is difficult for the typical organic TFT to meet the above-described technical requirements required for a switching device or a driving device. That is, technology for manufacturing an organic TFT that can meet the above-described technical requirements is required to commercialize a next generation flat panel display device such as an OLED display.

### SUMMARY OF THE INVENTION

The present invention provides a flat panel display device having a driving transistor that provides an increased turn-on current characteristic compared to that of a switching transistor.

The present invention also provides a method for manufacturing an organic semiconductor layer that can be used to selectively improve turn-on current characteristics of an organic TFT.

The present invention also provides a method for manufacturing a flat panel display device having a driving transistor that provides an increased turn-on current characteristic compared to that of a switching transistor.

Embodiments of the present invention provide a flat panel display devices having at least one organic thin film transistor (TFT) that uses an organic semiconductor layer having an increased particle size as an active layer, the flat panel display devices including: a first organic TFT having a first organic semiconductor active layer; and a second organic TFT having a second organic semiconductor active layer, a particle size of an organic semiconductor crystal of the first organic semiconductor active layer being greater than that of an organic semiconductor crystal of the second organic semiconductor active layer.

In some embodiments, the flat panel display devices further include an organic light emitting diode (OLED) electrically connected to the first organic TFT, the first organic TFT being used as a driving device controlling a current supplied to the OLED, and the second organic TFT being used as a switching device controlling an operation of the first organic TFT.

In other embodiments, the flat panel display devices further include a lower layer under the first and second organic semiconductor active layers, and a substrate under the lower layer, a surface treatment layer being between the first organic semiconductor active layer and the lower layer, and the surface treatment layer being transformed using one of ultraviolet (UV)-ozone treatment, oxygen plasma treatment, and laser ablation treatment, or formed by coating hydrophobic materials.

In still other embodiments, the surface treatment layer includes at least one of trichlorosilane-based materials including octadecyltrichlorosilane (OTS), benzyltrichlorosilane (BTS), dodecyltrichlorosilane (DTS), and hexamethyldishilanzane (HMDS).

In even other embodiments, the lower layer is formed of at least one of a silicon oxide, a silicon nitride, polyvinyl phenol (PVP), and acryl-based polymer materials.

In yet other embodiments, each of the first organic semiconductor active layer and the second organic semiconductor active layer include at least one of pentacene, tetracene, anthracene, naphthalene, α-6-thiophene, α-4-thiophene, perylene, rubrene, polythiophene, poly(p-phenylene vinylene (PPV), polyparaphenylene, polyfluorenes (PFs), polythiophenevinylene, polythiophene-heterocyclic aromatic copolymer, oligoacene of naphthalene, oligothiophene of α-5-thiophene, metal phthalocyanine, metal-free phthalocyanine, and derivatives thereof.

In other embodiments of the present invention, methods for manufacturing an organic semiconductor layer, the methods include: forming a lower layer; performing surface treatment on the lower layer to form a surface treatment layer on the lower layer; and forming an organic semiconductor layer on the surface treatment layer, the surface treatment layer increasing a size of a semiconductor crystal of the organic semiconductor layer formed on the surface treatment layer.

In still other embodiments, the forming of the surface treatment layer includes treating at least one region of the lower layer using at least one of UV-ozone treatment, oxygen plasma treatment, and laser ablation treatment.

In even other embodiments, the forming of the surface treatment layer includes coating at least one region of the lower layer with a hydrophobic material.

In yet other embodiments, the forming of the surface treatment layer uses at least one of inkjet technology and dropping technology to selectively coat the at least one region of the lower layer with the hydrophobic material.

In further other embodiments, the forming of the surface treatment layer includes coating an entire surface of a resulting structure where the lower layer has been formed with the hydrophobic material using at least one of spin coating technology and deposition technology, and then selectively removing a predetermined region of the hydrophobic material to selectively coat the at least one region of the lower layer with the hydrophobic material.

In still other embodiments, at least one of UV-ozone treatment, oxygen plasma treatment, and laser ablation treatment is used to selectively remove the predetermined region of the hydrophobic material.

In still other embodiments of the present invention, methods for manufacturing a flat panel display device having an organic TFT that can increase the crystal size of an organic semiconductor layer, the methods include: forming a lower layer on a substrate having a first region and a second region; performing surface treatment on the lower layer; and forming an organic semiconductor layer on the surface-treated lower layer, the performing of the surface treatment on the lower layer including selectively forming a surface treatment layer on a portion of the lower layer corresponding to the first region such that a portion of the organic semiconductor layer corresponding to the first region includes organic semiconductor crystal having a greater particle size than that of a portion of the organic semiconductor layer corresponding to the second region.

In some embodiments, the performing of the surface treatment on the lower layer includes selectively performing the surface treatment on the portion of the lower layer corresponding to the first region using at least one of UV-ozone treatment, oxygen plasma treatment, and laser ablation treatment.

In other embodiments, the performing of the surface treatment on the lower layer includes locally coating the portion of the lower layer corresponding to the first region with a hydrophobic material.

In still other embodiments, gate patterns are further formed on the substrate before the lower layer is formed, source/drain patterns are further formed on the lower layer before the performing of the surface treatment on the lower layer, and an OLED is further formed after the organic semiconductor layer is formed. At this point, the portion of the organic semiconductor layer corresponding to the first region is used as an active layer of a first organic TFT electrically connected to the OLED to serve as a driving device. The portion of the organic semiconductor layer corresponding to the second region is used as an active layer of a second organic TFT connected to the gate pattern of the first organic TFT to serve as a switching device.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a circuit diagram illustrating a unit pixel of an OLED display according to an embodiment of the present invention;

FIG. 2 is a cross-sectional view illustrating a unit pixel of an OLED display according to an embodiment of the present invention;

FIG. 3 is a cross-sectional view illustrating an embodiment of the present invention for forming an interface pattern;

FIG. 4 is a cross-sectional view illustrating another embodiment of the present invention for forming an interface pattern;

FIGS. 5A and 5B are cross-sectional views illustrating still another embodiment of the present invention for forming an interface pattern;

FIGS. 6A and 6B are electron microscope images illustrating a difference in particle sizes of an organic semiconductor layer depending on surface treatment; and

FIGS. 7A and 7B are voltage-current graphs illustrating a difference in an electric characteristic of an OLED display depending on whether surface treatment is performed or not.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the specification, the dimensions of layers and regions are exaggerated for clarity of illustration. It will also be understood that when a layer (or film) is referred to as being ‘on’ another layer or substrate, it can be directly on the other layer or substrate, or intervening layers may also be present. Also, though terms like a first, a second, and a third are used to describe various regions and layers in various embodiments of the present invention, the regions and the layers are not limited to these terms. These terms are used only to tell one region or layer from another region or layer. Therefore, a layer referred to as a first layer in one embodiment can be referred to as a second layer in another embodiment. An embodiment described and exemplified herein includes a complementary embodiment thereof.

Hereinafter, an exemplary embodiment of the present invention will be described with the accompanying drawings.

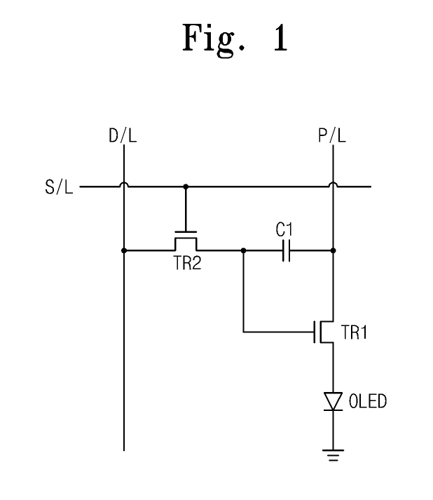

FIG. 1 is a circuit diagram illustrating a unit pixel of an OLED display according to an embodiment of the present invention.

Referring to FIG. 1, the unit pixel of the OLED display includes a driving transistor TR1 connected to an OLED, and a switching transistor TR2 having a drain electrode connected to the gate electrode of the driving transistor TR1.

According to the present invention, each of the driving transistor TR1 and the switching transistor TR2 may be an organic TFT that uses an organic semiconductor layer as an active layer.

The source electrode and the gate electrode of the switching transistor TR2 are connected respectively to a data line D/L and a scan line S/L crossing each other. In addition, the source electrode of the driving transistor TR1 is connected to a power line P/L crossing the scan line S/L. The drain electrode of the switching transistor TR2 and the gate electrode of the driving transistor TR1 are capacitively coupled to the power line P/L through a capacitor C1.

At this point, the capacitor C1 allows a potential applied from the data line D/L to be maintained during a time interval (i.e., one frame) between selection signals of the scan line S/L. Therefore, when the leakage current of the switching transistor TR2 increases, an image cannot be maintained for one frame. In this respect, the switching transistor TR2 needs to have a reduced leakage current characteristic.

Meanwhile, the driving transistor TR1 is turned on by charges stored in the capacitor C1 to deliver an electric power supplied from the power line P/L to the OLED. Therefore, to enhance the brightness of the OLED display, the driving transistor TR1 needs to have an increased turn-on current characteristic.

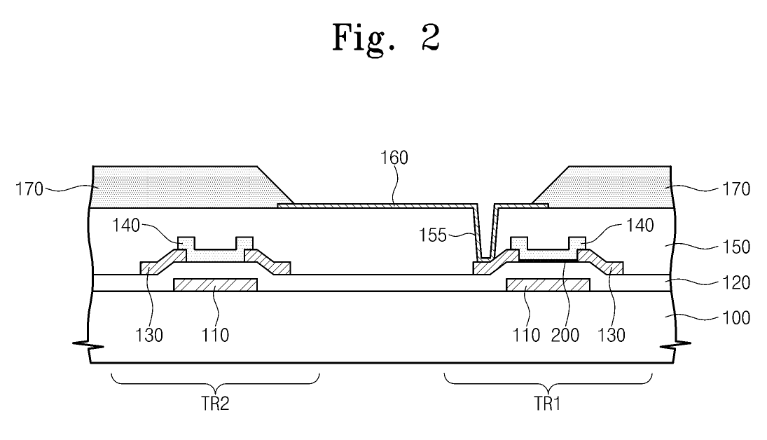

According to the present invention, the organic semiconductor layers of the driving transistor TR1 and the switching transistor TR2 are formed to have different particle sizes, respectively. More specifically, the organic semiconductor layer of the driving transistor TR1 has a greater particle size than that of the organic semiconductor layer of the switching transistor TR2. The structural characteristics of these transistors will be described later with reference to FIG. 2.

FIG. 2 is a cross-sectional view illustrating a unit pixel of an OLED display according to an embodiment of the present invention.

Referring to FIG. 2, gate patterns 110 are disposed in predetermined regions on a substrate 100, and a dielectric layer 120 is disposed on a resulting structure where the gate patterns 110 have been formed. The gate patterns 110 and the dielectric layer 120 are used as the gate electrodes and the gate dielectrics of the driving transistor and the switching transistor TR1 and TR2, respectively.

Source/drain patterns 130 exposing portions of the dielectric layer 120 corresponding to the gate patterns 110 are disposed on the dielectric layer 120. Organic semiconductor layers 140 used as the active layers of the driving transistor and the switching transistor TR1 and TR2 are disposed on the exposed portion of the dielectric layer 120 on the gate patterns 110.

According to an embodiment of the present invention, the substrate 100 may be formed of a glass material, or formed of a flexible material such as plastic to realize a flexible OLED display. The gate patterns 110 are formed of at least one of conductive materials. For example, the gate patterns 110 may be formed of at least one of metal materials such as Cr, Al, Au, Ni, Pt, Pd, Mo, and Ti, and compounds thereof. The gate patterns 110 may be formed in a single layer structure or a multi-layered structure. The dielectric layer 120 electrically separates the gate patterns 110 from the source/drain patterns 130, and may be formed of at least one of inorganic materials such as a silicon oxide and a silicon nitride, or at least one of organic materials such as polyvinyl phenol (PVP) and acryl-based polymer materials.

Also, the source/drain patterns 130 are formed of at least one of conductive materials. For example, the source/drain patterns 130 may be formed of at least one of metal materials such as Au, Pt, Pd, Ni, Cr, Al, Ag, Mo, and Ti, and compounds thereof. More specifically, the source/drain patterns 130 may include a lower metal layer directly contacting the dielectric layer 120, and an upper metal layer formed on the lower metal layer to improve a contact characteristic with the dielectric layer 120. According to one embodiment of the present invention, the lower metal layer may be formed of one of Ti, Al, and Cr. The upper metal layer may be formed of one of Au, Pt, Pd, and Ni.

The organic semiconductor layer 140 may include at least one of pentacene, tetracene, anthracene, naphthalene, α-6-thiophene, α-4-thiophene, perylene, rubrene, polythiophene, poly(p-phenylene vinylene (PPV), polyparaphenylene, polyfluorenes (PFs), polythiophenevinylene, polythiophene-heterocyclic aromatic copolymer, oligoacene of naphthalene, oligothiophene of α-5-thiophene, metal phthalocyanine, metal-free phthalocyanine, and derivatives thereof.

According to the present invention, the organic semiconductor layer 140 of the driving transistor TR1 has a greater particle size than that of the organic semiconductor layer of the switching transistor TR2 to have an increased charge mobility. Since the increase in the particle size causes reduction in effective resistance, an amount of a current per unit area in the driving transistor TR1 is greater than an amount of a current per unit area in the switching transistor TR2. Accordingly, the driving transistor TR1 may have an increased turn-on current characteristic compared to the switching transistor TR2.

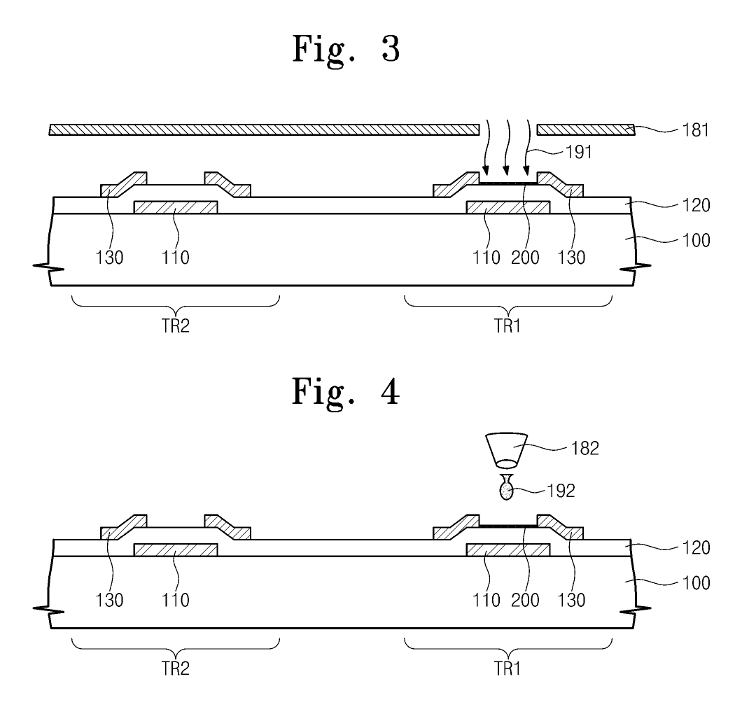

To realize a difference in a particle size, according to an embodiment of the present invention, an interface pattern 200 may be further interposed between the dielectric layer 120 and the organic semiconductor layer 140 of the driving transistor TR1. The interface pattern 200 may be formed using a method of selectively and physically transforming the upper surface of the dielectric layer 120 formed on the gate pattern 110 of the driving transistor TR1. The physical transformation may be performed using one of UV-ozone treatment, oxygen plasma treatment, and laser ablation treatment. Detailed description thereof will be described later with reference to FIG. 3.

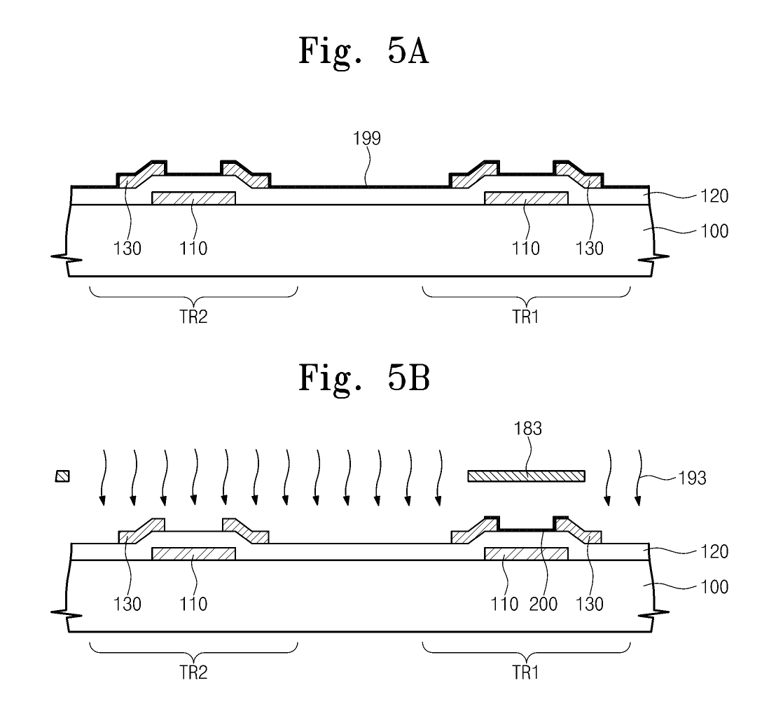

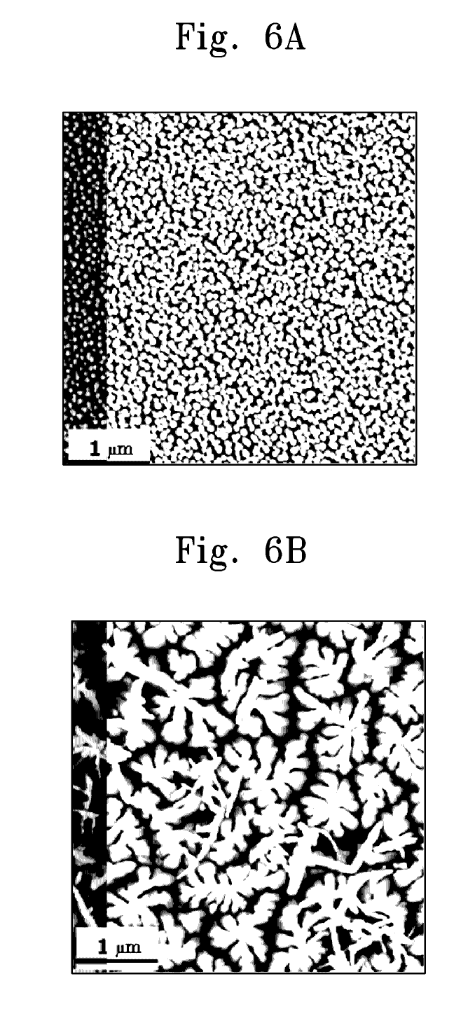

According to other embodiments, the interface pattern 200 may be formed using a method of locally forming at least one of hydrophobic materials on the dielectric layer 120 of the driving transistor TR1. The localization of the hydrophobic material may be achieved using one of inkjet technology or dropping technology which will be described again with reference to FIG. 4, or using a method of coating and selectively etching which will be described with reference to FIGS. 5A and 5B. At this point, the interface pattern 200 may be an organosilane-based self-assembled molecules layer. For example, the interface pattern 200 may be at least one of various kinds of trichlorosilane-based materials such as octadecyltrichlorosilane (OTS), benzyltrichlorosilane (BTS), and dodecyltrichlorosilane (DTS), and hexamethyldisilazane (HMDS).

In addition, a passivation layer 150 and a bank layer 179 are sequentially formed on the resulting structure where the driving transistor TR1 and the switching transistor TR2 have been formed. Also, an anode pattern 160 connected to the source/drain pattern 130 of the driving transistor TR1 through a contact hole 155 passing through the passivation layer 150 is formed on the passivation layer 150.

The passivation layer 150 allows the main top surface of the anode pattern 160 to be planarized while separating the anode pattern 160 from the switching transistor TR2. The bank layer 170 has a sloped sidewall profile and covers an upper edge of the anode pattern 160 to prevent an OLED to be formed on the anode pattern 160 from being open or short-circuited. In this respect, the bank layer 170 defines the shape of a pixel of an OLED display.

According to the present invention, the passivation layer 150 may include at least one of oxides and nitrides of a metal atom, and polyimide-based resins. The bank layer 170 may be formed of at least one of polyacryl-based organic materials and polyimide-based organic materials. Also, the anode pattern 160 may include at least one of transparent conductive materials such as indium-tin-oxide (ITO), indium-zinc-oxide (IZO), and ZnO, and metal materials such as Ag, Al, Mg, Ni, and Cr. For example, in the case where the anode pattern 160 is used as a transparent electrode, it may be formed of at least one of ITO, IZO, and ZnO. In the case where the anode pattern 160 is used as a reflective electrode, it may be formed in a multi-layered structure in which at least one of ITO, IZO, and ZnO is stacked on at least one of metal materials such as Ag, Al, Mg, Ni, and Cr.

Meanwhile, the substrate 100, the gate pattern 110, the dielectric layer 120, the source/drain patterns 130, the organic semiconductor layer 140, the passivation layer 150, the anode pattern 160, the bank layer 170, and the interface pattern 200 are not limited to the above-described materials. Various materials known in the art may be readily used for these elements.

FIG. 3 is a cross-sectional view illustrating forming an interface pattern according to an embodiment of the present invention.

Referring to FIG. 3, this embodiment includes performing surface treatment 191 on the resulting structure where the source/drain patterns 130 described with reference to FIG. 2 have been formed. The surface treatment 191 includes physically damaging the upper surface of the dielectric layer 120 using a predetermined first surface treatment mask 181 in the region where the driving transistor TR1 is formed. At this point, the firs surface treatment mask 181 may have an opening locally exposing the upper surface of the dielectric layer 120 exposed by the source/drain patterns 130.

More specifically, the surface treatment may be performed through UV-ozone treatment. The UV-ozone treatment may include irradiating an UV having a wavelength of about 234 nm on the exposed upper surface of the dielectric layer 120 of the driving transistor TR1 for about 10 seconds through 5 minutes. The UV irradiation transforms the coupling state of oxygen, carbon, and hydrogen existing on the exposed upper surface of the dielectric layer 120 to create, on the dielectric layer 120, the interface pattern 200 contributing to increasing the particle size of the organic semiconductor layer 140.

According to other embodiments, the surface treatment 191 may include physically damaging the dielectric layer 120 of the driving transistor TR1 exposed through the first surface treatment mask 181 using plasma. At this point, the plasma treatment may be performed under a low temperature and atmospheric pressure ambient including oxygen atoms (for example, an oxygen ambient or an ambient including a mixture of an oxygen gas and an argon gas). Like the UV, the plasma transforms the exposed upper surface of the dielectric layer 120 to create the interface pattern 200 on the dielectric layer 120.

According to another embodiment, the surface treatment 191 may include physically damaging the dielectric layer 120 of the driving transistor TR1 exposed through the first surface treatment mask 181 using laser ablation technology. A laser used for this purpose may be a KrF excimer laser, a Nd:YAG laser (532 nm), or a carbon dioxide laser (10,600 nm), but is not limited thereto. The laser transforms the exposed upper surface of the dielectric layer 120 to create the interface pattern 200 on the dielectric layer 120.

FIG. 4 is a cross-sectional view illustrating forming an interface pattern according to another embodiment of the present invention.

Referring to FIG. 4, the forming of the interface pattern includes locally forming the interface pattern 200 formed of a hydrophobic material on the dielectric layer 120 of the driving transistor TR1. To locally form the hydrophobic material, this embodiment may use well-known inkjet technology or dropping technology. The inkjet technology or dropping technology includes locally spraying liquid drops 192 onto a predetermined region using a predetermined spraying unit 182. Accordingly, unlike the embodiment described with reference to FIG. 3, this embodiment does not require a separate mask.

At this point, the hydrophobic material for the interface pattern 200 may be an organosilane-based self-assembled molecules layer. For example, the interface pattern 200 may be at least one of various kinds of trichlorosilane-based materials such as octadecyltrichlorosilane (OTS), benzyltrichlorosilane (BTS), and dodecyltrichlorosilane (DTS), and hexamethyldisilazane (HMDS), but is not limited thereto.

FIGS. 5A and 5B are cross-sectional views illustrating forming an interface pattern according to still another embodiment of the present invention.

Referring to FIG. 5A, the forming of the interface pattern includes coating a surface treatment layer 199 formed of the above-described hydrophobic material on the entire surface of the resulting structure where the source/drain patterns 130 have been formed. The coating may be performed using at least one of well-known spin coating technology or vacuum deposition technology.

Referring to FIG. 5B, the interface pattern 200 locally remaining on only the upper portion of the driving transistor TR1 is formed by selectively removing a predetermined region of the surface treatment layer 199. This operation is performed such that at least a portion of the surface treatment 199 located on the switching transistor TR2 is removed. Also, according to this embodiment, the interface pattern 200 may cover the adjacent upper edges of the source/drain patterns 130 extending from a region between the source/drain patterns 130.

According to one embodiment of the present invention, the removing of the surface treatment layer 199 may be performed using at least one of UV-ozone treatment, oxygen plasma treatment, and laser ablation technology. However, in an aspect of a process condition, the removing of the surface treatment layer 199 may be performed using higher power or performed for a longer process time than that of the forming of interface pattern 200 on the dielectric layer 120. Also, this embodiment may be performed using a second surface treatment mask 183 covering the driving transistor TR1 so that the interface pattern 200 may remain in a region of the driving transistor TR1.

For example, the UV-ozone treatment for the removing of the surface treatment layer 199 may include irradiating an UV having a wavelength of about 234 nm onto the surface treatment layer 199 for about 2 minutes through 20 minutes. Also, the plasma treatment for the removing of the surface treatment layer 199 may be performed using higher plasma density or performed for a longer process time than that of the case described with reference to FIG. 3. Likewise, the laser irradiation for the removing of the surface treatment layer 199 may be also performed under a condition of higher laser power or a longer irradiation time than that of the case described with reference to FIG. 3.

In a method for an OLED display according to the present invention, the organic semiconductor layer 140 used as the active layer of the organic TFT is formed on the interface pattern 200 formed using the method descried with reference to FIGS. 3, 4, 5A, and 5B. In this case, since the driving transistor TR1 has the interface pattern 200 as described above, the particle size of the organic semiconductor layer 140 formed on the interface pattern 200 is greater than that of the organic semiconductor layer on the switching transistor TR2 where the interface pattern 200 is absent.

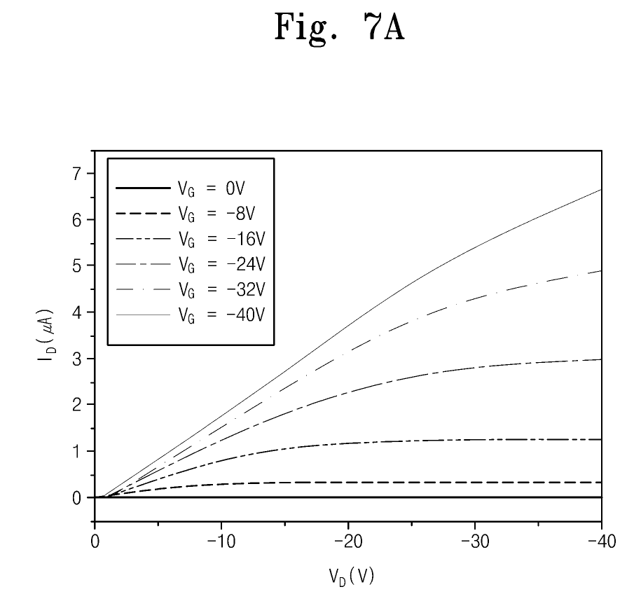

FIGS. 6A and 6B are atomic force microscopy (AFM) photos illustrating a difference in particle sizes of an organic semiconductor layer depending on surface treatment.

In detail, FIG. 6B is an electron microscope photo of an organic semiconductor layer (described with reference to FIG. 3) formed on the dielectric layer after the UV-ozone treatment has been performed on the dielectric layer for three minutes, and FIG. 6A is an AFM photo of an organic semiconductor layer formed on a dielectric layer on which the UV-ozone treatment has not been performed. At this point, all the organic semiconductor layers of two samples were pentacene, and the dielectric layers were acryl-based polymers.

In case of the sample of FIG. 6A on which the UV-ozone treatment has not been performed, the particle size of the organic semiconductor layer has an order of magnitude of about 50 nm. On the other hand, in case of the sample of FIG. 6B on which the UV-ozone treatment has been performed, the particle size of the organic semiconductor layer has an order of magnitude of about 1 μm (As illustrated, since the crystal of the organic semiconductor layer may not be spherical, the term “particle size” means the length of the inseparable crystal structure). From the foregoing, it is revealed that when an interface pattern is formed through the surface treatment, an organic semiconductor layer formed on the resulting structure has a far greater particle size than that of an organic semiconductor layer on which the surface treatment has not been performed.

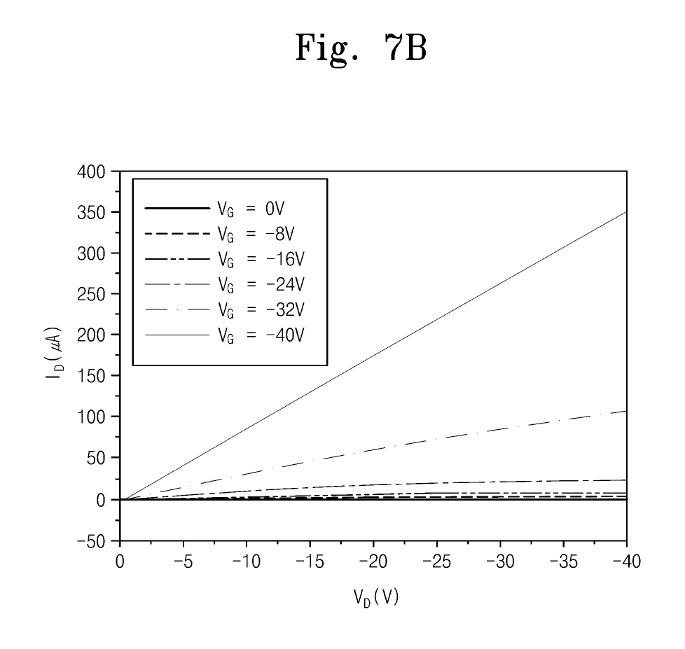

FIGS. 7A and 7B are voltage-current graphs illustrating a difference in an electric characteristic of an OLED display depending on whether surface treatment is performed or not. At this point, FIG. 7A illustrates results measured from the organic TFT having the organic semiconductor layer formed on the dielectric layer on which the UV-ozone treatment has not been performed as an active layer, and FIG. 7B illustrates results measured from the organic TFT having the organic semiconductor layer (described with reference to FIG. 3) formed on the dielectric layer on which the UV-ozone treatment has been performed for three minutes as an active layer.

The organic TFT of FIG. 7B on which the UV-ozone treatment has been performed had an about 50 times greater turn-on current characteristic than that of the organic TFT of FIG. 7A on which the UV-ozone treatment has not been performed. Consequently, it is revealed that an organic TFT may have a remarkably improved turn-on current characteristic when an interface pattern is formed through the surface treatment.

The present invention provides a method that can selectively increase the particle size of an organic semiconductor layer as illustrated in FIGS. 6A and 6B. The selective increase of the particle size causes a selective increase in the turn-on current of an organic TFT as illustrated in FIGS. 7A and 7B. In this respect, the present invention can meet technical requirements required for commercialization of an OLED display. That is, since a current supplied to an OLED can be increased when an organic semiconductor layer having an increased particle size is used as the active layer of a driving device, the brightness characteristic of an OLED display can be increased.

In addition, since the selective improving of the turn-on current characteristic increases a degree of freedom of a manufacturing process or a design associated with manufacturing of a switching transistor, the leakage current characteristic of the switching transistor can be selectively reduced. The reduction in the leakage current of the switching transistor can increase the color reproduction ability of the OLED display.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A flat panel display device having an organic thin film transistor (TFT), the flat panel display device comprising:
a first organic TFT having a first organic semiconductor active layer; and
a second organic TFT having a second organic semiconductor active layer,
a particle size of an organic semiconductor crystal of the first organic semiconductor active layer being greater than that of an organic semiconductor crystal of the second organic semiconductor active layer.

2. The flat panel display device of claim 1, further comprising an organic light emitting diode (OLED) electrically connected to the first organic TFT, the first organic TFT being used as a driving device controlling a current supplied to the OLED, and the second organic TFT being used as a switching device controlling an operation of the first organic TFT.

3. The flat panel display device of claim 1, further comprising:
a lower layer under the first and second organic semiconductor active layers;
a substrate under the lower layer, and
a surface treatment layer between the first organic semiconductor active layer and the lower layer,
wherein the surface treatment layer is transformed using one of ultraviolet (UV)-ozone treatment, oxygen plasma treatment, and laser ablation treatment or is formed by coating at least one of hydrophobic materials.

4. The flat panel display device of claim 3, wherein the surface treatment layer comprises at least one of trichlorosilane-based materials including octadecyltrichlorosilane (OTS), benzyltrichlorosilane (BTS), dodecyltrichlorosilane (DTS), and hexamethyldishilanzane (HMDS).

5. The flat panel display device of claim 3, wherein the lower layer is formed of at least one of a silicon oxide, a silicon nitride, polyvinyl phenol (PVP), and acryl-based polymer materials.

6. The flat panel display device of claim 1, wherein each of the first organic semiconductor active layer and the second organic semiconductor active layer comprises at least one of pentacene, tetracene, anthracene, naphthalene, α-6-thiophene, α-4-thiophene, perylene, rubrene, polythiophene, poly(p-phenylene vinylene (PPV), polyparaphenylene, polyfluorenes (PFs), polythiophenevinylene, polythiophene-heterocyclic aromatic copolymer, oligoacene of naphthalene, oligothiophene of α-5-thiophene, metal phthalocyanine, metal-free phthalocyanine, and derivatives thereof.

7. A method for manufacturing an organic semiconductor layer, the method comprising:
forming a lower layer;
performing surface treatment on the lower layer to form a surface treatment layer on the lower layer; and
forming an organic semiconductor layer on the surface treatment layer, the surface treatment layer increasing a size of a semiconductor crystal of the organic semiconductor layer formed on the surface treatment layer.

8. The method of claim 7, wherein the forming of the surface treatment layer comprises treating at least one region of the lower layer using at least one of UV-ozone treatment, oxygen plasma treatment, and laser ablation treatment.

9. The method of claim 7, wherein the forming of the surface treatment layer comprises locally coating at least one region of the lower layer with a hydrophobic material.

10. The method of claim 9, wherein the forming of the surface treatment layer comprises locally coating the at least one region of the lower layer with the hydrophobic material using at least one of inkjet technology and dropping technology.

11. The method of claim 9, wherein the forming of the surface treatment layer comprises:
coating an entire surface of a resulting structure having the lower layer with the hydrophobic material using at least one of spin coating technology and deposition technology; and
patterning the hydrophobic material to locally leave the hydrophobic material on at least one region of the lower layer.

12. The method of claim 11, wherein the patterning of the hydrophobic material is performed using at least one of UV-ozone treatment, oxygen plasma treatment, and laser ablation treatment.

13. The method of claim 9, wherein the hydrophobic material comprises at least one of trichlorosilane-based materials including octadecyltrichlorosilane (OTS), benzyltrichlorosilane (BTS), dodecyltrichlorosilane (DTS), and hexamethyldishilanzane (HMDS).

14. The method of claim 7, wherein the lower layer is formed of at least one of a silicon oxide, a silicon nitride, polyvinyl phenol (PVP), and acryl-based polymer materials.

15. The method of claim 7, wherein the organic semiconductor layer comprises at least one of pentacene, tetracene, anthracene, naphthalene, α-6-thiophene, α-4-thiophene, perylene, rubrene, polythiophene, poly(p-phenylene vinylene (PPV), polyparaphenylene, polyfluorenes (PFs), polythiophenevinylene, polythiophene-heterocyclic aromatic copolymer, oligoacene of naphthalene, oligothiophene of α-5-thiophene, metal phthalocyanine, metal-free phthalocyanine, and derivatives thereof.

16. A method for manufacturing a flat panel display device having an organic TFT, the method comprising:
forming a lower layer on a substrate having a first region and a second region;
performing surface treatment on the lower layer; and
forming an organic semiconductor layer on the surface-treated lower layer,
wherein the performing of the surface treatment on the lower layer comprises selectively forming a surface treatment layer on a portion of the lower layer corresponding to the first region such that a portion of the organic semiconductor layer corresponding to the first region includes organic semiconductor crystals having a greater particle size than that of a portion of the organic semiconductor layer corresponding to the second region.

17. The method of claim 16, wherein the performing of the surface treatment on the lower layer comprises selectively performing the surface treatment on the portion of the lower layer corresponding to the first region using at least one of UV-ozone treatment, oxygen plasma treatment, and laser ablation treatment.

18. The method of claim 16, wherein the performing of the surface treatment on the lower layer comprises locally coating the portion of the lower layer corresponding to the first region with a hydrophobic material.

19. The method of claim 18, wherein the performing of the surface treatment on the lower layer comprises locally coating the portion of the lower layer corresponding to the first region with a hydrophobic material using at least one of inkjet technology and dropping technology.

20. The method of claim 18, wherein the performing of the surface treatment on the lower layer comprises:
coating an entire surface of a resulting structure where the lower layer has been formed with the hydrophobic material using at least one of spin coating technology and deposition technology; and
patterning the hydrophobic material to locally leaving the hydrophobic material on the portion of the lower layer corresponding to the first region.

21. The method of claim 20, wherein the patterning of the hydrophobic material is performed using at least one of UV-ozone treatment, oxygen plasma treatment, and laser ablation treatment.

22. The method of claim 18, wherein the hydrophobic material comprises at least one of trichlorosilane-based materials including octadecyltrichlorosilane (OTS), benzyltrichlorosilane (BTS), dodecyltrichlorosilane (DTS), and hexamethyldishilanzane (HMDS).

23. The method of claim 16, wherein the lower layer is formed of at least one of a silicon oxide, a silicon nitride, polyvinyl phenol (PVP), and acryl-based polymer materials.

24. The method of claim 16, wherein the organic semiconductor layer comprises at least one of pentacene, tetracene, anthracene, naphthalene, α-6-thiophene, α-4-thiophene, perylene, rubrene, polythiophene, poly(p-phenylene vinylene (PPV), polyparaphenylene, polyfluorenes (PFs), polythiophenevinylene, polythiophene-heterocyclic aromatic copolymer, oligoacene of naphthalene, oligothiophene of α-5-thiophene, metal phthalocyanine, metal-free phthalocyanine, and derivatives thereof.

25. The method of claim 16, further comprising:
forming gate patterns on the substrate before the forming of the lower layer;
forming source/drain patterns on the lower layer before the performing of the surface treatment on the lower layer; and
forming an OLED after the forming of the organic semiconductor layer,
wherein the portion of the organic semiconductor layer corresponding to the first region is used as an active layer of a first organic TFT electrically connected to the OLED to serve as a driving device, and
the portion of the organic semiconductor layer corresponding to the second region is used as an active layer of a second organic TFT connected to the gate pattern of the first organic TFT to serve as a switching device.
